(19) United States
(12) Patent Application Publication
(10) Pub. No.: US 2012/0031465 A1
(43) Pub. Date: Feb. 9, 2012

(54) SOLAR MODULE IN AN INSULATING GLASS COMPOSITE METHOD FOR PRODUCTION AND USE

(75) Inventor: Rene Battistutti, Klagenfurt (AT)

(73) Assignee: Energetica Holding GMBH, Viktring (AT)

(21) Appl. No.: 13/144,035

(22) PCT Filed: Jan. 8, 2010
(86) PCT No.: PCT/EP10/00050

§ 371 Date: Sep. 23, 2011

(30) Foreign Application Priority Data
Jan. 9, 2009 (DE) 10 2009 004 195.8

(51) Int. Cl. H01L 31/052; H01L 31/0203; H01L 31/048

(52) U.S. Cl. 136/246; 136/251; 438/67; 257/E31.117

(57) ABSTRACT

Solar module comprising a number of solar cells, arranged and fixed in an insulating glass composite in the cavity between a front and a rear pane, wherein the solar cells are fixed to the inside of at least one of the panes by soldering.

The invention relates to the electrical and mechanical assembly of mono- or multi-crystalline (c-Si) solar modules on a glass pane and integration thereof in an insulating glass composite, and to the production of an insulating glass pane with c-Si modules inside, without lamination. Insulating glass panes of this type with integrated c-Si modules can be produced cost effectively and can be integrated very easily into building facades or used as roof arrays or free-standing elements.

A solar module, photovoltaic module or solar generator converts the light from the sun directly into electric energy. As the most important components, it contains a plurality of solar cells.

Solar modules are used individually or interconnected into groups in photovoltaic plants, off-grid consumers, or for the power supply of spacecrafts. A solar module is characterized by the connected electrical load (e.g. idle voltage and short-circuit current) thereof. Same are dependent upon the properties of the individual solar cells and on the electrical interconnection of the solar cells within the module.

In order to satisfy the demands placed on a system for solar-generated power, solar cells are grouped together by means of a plurality of different materials, to form a solar module. This composite fulfills the following purposes:
transparent, radiation and weather-resistant covering
robust electrical connections
protection of the brittle solar cell from mechanical influences
protection of the solar cells and electrical connections from moisture
adequate cooling of the solar cells
protection of the electrically conducting components from accidental contact
handling and fastening means

Solar modules exist in different designs, using different types of solar cells. Below, the structure will be explained based on the module type that is used most commonly world-wide:
A glass pane (usually so-called tempered safety glass) on the side facing the sun.
A transparent layer of plastic material (ethylene vinyl acetate (EVA) or silicone rubber), in which the solar cells are embedded,
mono- or polycrystalline solar cells that are electrically interconnected by means of soldered strings,
rear-side lamination using a weatherproof plastic composite film, e.g. made of polyvinyl fluoride (Tedlar) and polyester,
junction box with suppressor diode or bypass diode and terminal
an aluminum profile frame for protection of the glass pane during transport, handling and assembly, for fastening and for stiffening the composite.

In DE202008003967U1, there is described an assembly of solar photovoltaic cells that are configured in an insulating glass composite. The assembly is configured between two panes that are sealed using a full-perimeter sealing strip to form a sealed cavity.

The photovoltaic cells are secured on the inside of the insulating glass composite using a pressure-sensitive adhesive. However, this brings with it the shortcomings of the undesirable outgassing of the adhesive in the interior and a complex assembly.

In general, thin-film PV cells, such as those described in this utility patent, are designed as single cells—because the appropriate series/parallel connections can be made already in the thin-film layout. When 2 or more thin-film cells are configured in an insulating glass composite, the transparency is usually crucial, such that no thin-film cells can be placed in a, for example, central region, in order that the insulating glass composite can be used also as a window.

In EP00499075B1, a solar cell string is proposed, wherein spaced-apart solar cells are connected in series via contact elements that permit a relative movement between the cells.

In a customary embodiment, described, for example, in EP01018166B1, solar cells that are contacted in such a way and connected in series or in parallel are provided on both sides with an encapsulation material, for example and customarily EVA (ethylene vinyl acetate) in a lamination machine.

In the aforementioned prior art, there exists the shortcoming of a complex assembly and mounting of the solar cells by means of lamination on appropriate carrier plates.

The invention is therefore based on the aim of mounting a plurality of solar cells according to DE202008003967U1 in such a way that a more cost-effecting mounting and improved assembly are provided.

In order to achieve this aim, the invention is characterized by the technical teaching of claim 1.

It is an essential feature of the invention that the solar cells are arranged in the interior of an insulating glass member, the insulating glass member comprising an insulating glass module that, in turn, comprises at least one front pane and at least one rear pane disposed spaced apart from the front pane and an interior space that is preferably filled with an inert gas, and that the solar cells are fixed in place on the inside of at least one of the panes by means of soldering.

The invention uses mono- or multi-crystalline modules, that is to say c-Si cells. Advantageously, c-Si cells have dimensions from e.g. 157×157 mm to approximately 120×120 mm and can be arranged virtually as desired, depending on the intended soldered supporting points on the glass. Consequently, a transparency in certain regions can be achieved, or a light transmission of e.g. 20% can be achieved. Additionally, the series or parallel connection can also be selected as freely as optimal for the given application. With this, the solar modules according to the invention can be used also as windows having good optical transparency.

The contacts can, of course, be applied very easily directly and routed thermally secured on the inside of the glass through the hollow profile to the outside along with the primary and secondary insulations thereof. Any diodes or resistors can, of course, also be integrated very easily in this arrangement.

This presents the essential advantage that the configuration of the solar cells in the interior space of such an insulating glass module provides for a significantly improved mounting, because now the solar cells can simply be placed on the inside of the rear pane, without the need for particularly elaborate mounts. All that is required is a simple positional securing or positional fixing, such as can be effected, e.g. by drops of adhesive that are placed, for example, on the underside of the solar cells and that produce an adhesive bond with the inside of the rear pane.

In the present invention, mono- or multi-crystalline solar cell modules are used that are provided with strings capable of being soldered and having good electrical conductivity, that connect the underside of a cell to the upper-side structure of a cell that is connected in series and then produce the connections of a module. The type of series and parallel connection can be selected according to the prior art and the number of these connecting strings likewise can be selected according to the prior art, two strings being a customary number.

In another embodiment of the invention, provision is made that the strings connecting the cells are soldered to the inside of the rear pane for positional securing of the solar cells.

This results in a particularly simple mounting and, therefore, also in a simple assembly of insulating glass modules of this type having solar cells fixed therein serving purely for positional securing.

Lamination therefore is accordingly no longer required and the solar cells can be simply placed into a “snow-white's coffin,” so to speak, and held there in a positionally secured manner.

According to the invention, the interior space is designed in the form of a cavity and filled with an inert gas. This is a difference over the prior art, because in the prior art it is provided for electrical reasons that the surface of solar cells is covered completely with a plastic layer that is optically transmissive, that is to say, designed to be transparent or translucent, and serves to mount the solar cells.

There is no need for this according to the present invention, as a result of which significant costs are saved. In the prior art, a so-called EVA coating (ethylene vinyl acetate) is used.

There is no need for this according to the invention, and the manufacturing costs of a photovoltaic module of this type are therefore reduced substantially.

Owing to the elimination of the coating plastic covering of the solar cells, there exists in the interior space of the insulating glass module the risk of a reflection and, therefore, loss of efficiency. In order to prevent this, provision is made that an antireflective coating is applied onto the top surface of the front pane. An embossed texture on the surface of the front pane can also be used.

It is a further essential feature of the invention that it is a prerequisite, due to the solar cells being housed in an insulating glass module, that the insulating glass module is sealed on all sides and filled with the aforementioned inert gas or with air or evacuated. For this purpose, provision is made that a full-perimeter hollow profile is arranged peripherally which is fixed on one hand to the insides of the front and rear pane using a first adhesive agent and which carries on the face end thereof a sealing means that holds and supports this spacer profile in a sealing manner around the full perimeter in the space between the front pane and the rear pane.

In a first embodiment of the present invention, the solar cells are positioned on the inside of the rear pane, using only an adhesion-promoting adhesive.

In a second embodiment, the solar cells are soldered in the region of the strings thereof to associated conducting layers that are configured on the surface of the rear pane. The invention also provides for a combination of the two aforementioned ways of positional securing.

It is of particular advantage that these conducting layers can additionally also be provided peripherally and serve for leading the electric contacts in and out, to the outside.

In a third embodiment, provision is made that the string of the solar cells on the underside is eliminated and an electrically conductive connection to the conducting layer configured on the inside of the rear pane is instead produced via a soldered connection. In this manner, both an electric contacting and a positional securing of the solar cells in the interior space of the insolating glass module are used. This is particularly favorable during the production and is a particularly simple method of production.

A preferred method for producing such a photovoltaic module comprises the following process steps:
1. Production of standard commercial solar cells with electrical connection of the associated strings, such that this photovoltaic module is electrically conductive and functional.
2. Insertion of the thus prepared, fully functional photovoltaic module into an opened insulating glass composite, with the front pane, for example, still removed.
3. The solar cells placed onto the rear pane are secured on the rear pane using a suitable position-securing adhesive and the incoming and outgoing leads are created by means of soldering-on conducting layers capable of being soldered, on the inside of the rear pane.
4. Affixing of the peripheral full-perimeter hollow profile using at least one adhesive agent for fixing the hollow profile to the inside of the rear pane.
5. Affixing of the front pane to the prepared hollow profile with creation of an adhesive contact of the inside of the front pane to the adhesive agent on the hollow profile.
6. Face-end full-perimeter application of a sealing agent for sealing the hollow profile in the insulating glass composite between the front pane and the rear pane.
7. The interior space in the insulating glass module can be filled with air or with an inert gas, or can be evacuated.

In a second method variant, all method steps are carried out as listed above, except for the method step that the solar cells are fixed in place on the inside of the rear pane using an adhesion-promoting adhesive.

Instead, the strings that serve for the electrical interconnection of the solar cells are fixed in place by means of a soldered or friction-welded connection on associated conducting layers capable of being soldered, on the inside of the rear pane.

In a third method variant of the method according to the invention, provision is now made instead of the soldering of the underside strings of the solar cells that the underside strings are eliminated and the solar cells are now soldered in an electrically conductive manner directly to the conducting layers configured on the inside of the rear pane.

The subject matter of the present invention is defined not only by the subject matter of the individual claims, but also by the combination of the individual claims with one another.

All of the specifications and features disclosed herein, including in the abstract, in particular the three-dimensional embodiment shown in the drawings, are claimed as essential to the invention either individually or in combination, to the extent that they are novel over the prior art.

The invention will be explained in more detail below, in conjunction with drawings illustrating a number of routes of implementation. Additional features and advantages of the invention will become apparent from the drawings and from their description.

In the drawings,

FIG. 1 shows a perspective illustration of two solar cells that are electrically interconnected by means of two strings and comprise a number of individual cells,

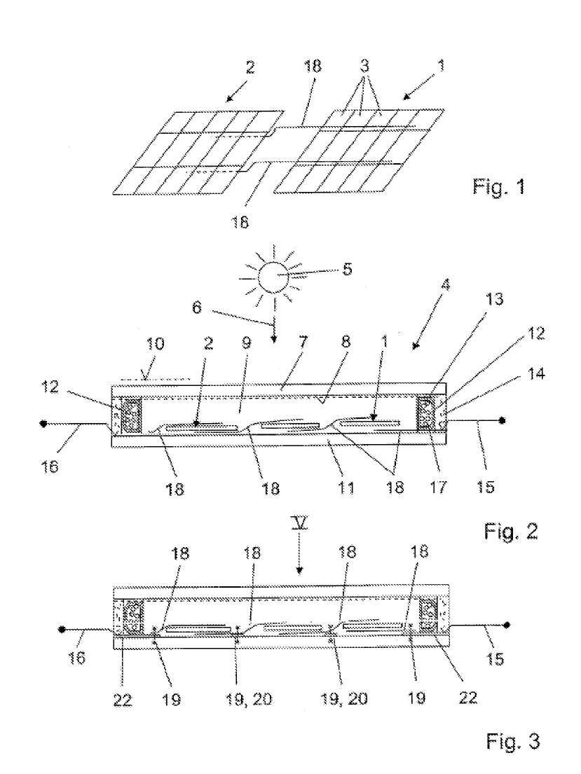

FIG. 2 shows a section through a first variant of an insulating glass module, with a positionally securing fixing by means of a pressure-sensitive adhesive of the solar cells according to FIG. 1,

FIG. 3 shows a variant of FIG. 2,

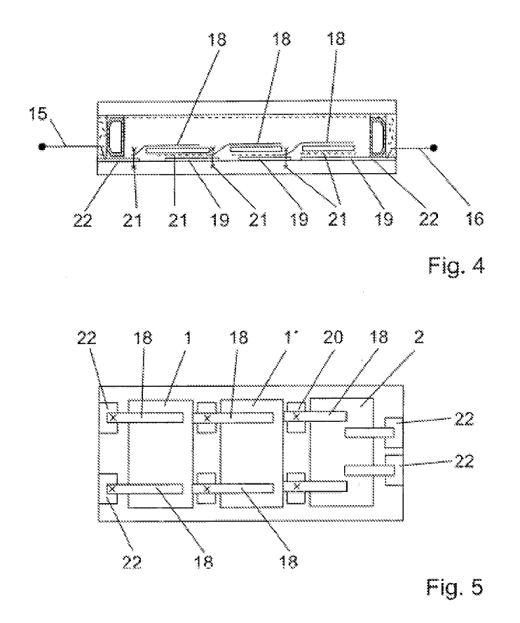

FIG. 4 shows a variant of FIGS. 2 and 3,

FIG. 5 shows the top view of the insulating glass module in the direction of the arrow V in FIG. 4, with depiction of additional details.

FIG. 1 generally shows a photovoltaic module comprising two mutually interconnected solar cells 1, 2 which are connected to one another in an electrically conductive manner via strings 18 in a manner not specifically shown. Each solar cell 1, 2 comprises a multiplicity of electrically interconnected individual cells 3. The various methods of electrically interconnecting these solar cells will not be discussed in the context of the present invention.

It is now important that the solar cells 1, 2 are placed into an insulating glass module 4 fixed in a positionally secured manner, during which process the solar cells 1, 2 are placed according to the aforementioned first method variant onto a rear pane 11 made of glass, and fixed in place on the surface of this rear pane 11 with the aid of a pressure-sensitive adhesive not specifically shown. The strings 18 are connected to one another in this arrangement so as to be electrically conductive and are led out under the hollow profile 12 at the face end. The contacts 15, 16 are therefore capable of being electrically contacted.

After fixing the solar cells 1, 2 in place on the inside of the rear pane 11, the hollow profile 12 is now inserted and glued to the inside of the rear pane 11 using a suitable adhesive agent 13.

Afterwards the front pane 7 is placed on, which is likewise connected to the hollow profile 12 using a suitable adhesive agent 13. The adhesive agent 13 is designed such that it is thermally elastic and allows for a certain tolerance of movement of the two panes 7, 11 relative to one another.

A sealing agent 14 is then applied extending frontally around the full perimeter, which joins the hollow profile 12 in a sealing manner to the panes 7, 11 and thereby produces a tight, that is to say, air-tight, seal, such that the interior space 9 of the insulating glass module 4 is closed off in a sealing manner from the atmosphere. Therefore, no water vapor will be present in the interior space 9, in particular also because a suitable desiccant 17 is arranged in the hollow profile 12 and has access to the interior space 9 of the insulating glass module through appropriate air-carrying channels.

A coating 8 which is designed as an antireflective coating can be provided on the inside of the front pane 7.

When placing the front pane 7 onto the adhesive agent 13 and sealing using the sealing agent 14, an air exchange of the atmospheric air present in the interior space 9 against an inert gas can be carried out at the same time; however, as a rule, air can also remain in the interior space 9, or the interior space can be evacuated.

Suitable insolation from the sun 5 in the direction of the arrow 6 onto the front pane 7 of the insulating glass module 4 therefore leads to a suitable solar energy influx into the interior space 9, the external coating 10 on the outside of the front pane 7 preventing a reflection to the outside.

This results in an excellent exposure in the interior space 9 through the transparent or translucent front pane 7 on the solar cells 1, 2, which therefore operate at a high degree of efficiency. There is no risk of soiling and no risk of water vapor forming. Ageing symptoms are minimized due to the solar cells being enveloped by dry air or by an inert dry gas.

This makes for a long service life of the solar cells at a high degree of efficiency.

The solar cells lie free in a “snow white's coffin”, so to speak, without being covered by a diffuse cover layer that takes away significant light intensity, and therefore this entire array operates at a significantly higher degree of efficiency.

A modified embodiment is shown in FIG. 3, where it can be see that the strings 18 running on the underside of the solar cells 1 are fixed in place in a position-securing manner on the surface of the rear pane 11 in such a way that conducting layers 19 are applied on the rear pane 11 which are preferably designed so as to be capable of being soldered. Conducting layers of this kind can consist, e.g. of a conductive silver paste or of other suitable conducting layers. In this region the strings 18 are soldered on, which, however, does not produce an electrical contact but merely serves for positional securing.

Only in the outer regions are the conducting layers 19 continued so as to form electrically conductive contact areas 22, which are then routed to the outside through or under the hollow profile 12. In this manner, a particularly favorable routing of the contacts 15, 16 to the outside exists without the need for hollow pass-throughs.

The conducting layers provided in the central region, accordingly, represent only a thermal fixing 20, without any importance being placed on electrical contacting.

In the embodiment according to FIG. 4 the strings 18 configured on the underside of the solar cells 1 are eliminated and same are now connected directly in an electrically conductive manner via a soldered connection 21 to the electrically conducting layers 19, where they are contacted.

Therefore, thermal securing connections are no longer present, but the soldered connections 21 serve at the same time for the positional securing of said solar cells and at the same time also for the electrical connections of the individual cells and of the solar cells to one another.

Here too, the contact areas 22 are routed to the outside under the hollow profile 12

FIG. 5 shows the top view of the array of FIG. 3 in the direction of the arrow V, where it can be seen that each string has a contact area 22 associated therewith on the outside, and the strings extending in the interior space in the central region are configured positionally secured and electrically contacted via said conducting layer 19 and the soldered connection 21 present there, on the rear pane 11

### DRAWING LEGEND

1 solar cell
2 solar cell
3 single cell
4 insulating glass module
5 sun
6 direction of arrow
7 front pane
8 coating (inside)
9 interior space
10 coating (outside)
11 rear pane
12 hollow profile
13 adhesive agent
14 sealing agent
15 contact
16 contact
17 desiccant
18 string
19 conducting layer (capable of being soldered)
20 thermal securing
21 soldered connection
22 contact area

1. A solar module comprising a plurality of solar cells (1, 2) that are configured in an insulating glass composite in the space between a front and rear pane (7, 11) and secured there, wherein the solar cells (1, 2) are fixed in place on the inside of at least one of the panes (7, 11) by soldering.

2. A solar module comprising a plurality of solar cells that are configured and secured in an insulating glass composite in the space between a front and rear pane, wherein the solar cells (1, 2) are secured to the inside of the rear pane (11) by means of a simple positional securing by means of drops of adhesive.

3. The solar module according to claim 1, wherein the solar cells (1, 2) comprise mono- or multi-crystalline solar cells that are provided with strings (18) capable of being soldered and having good electrical conductivity, that connect the underside of a cell (1, 2) to the upper-side structure of a cell (1, 2) that is connected in series and then produce the connections of a module.

4. The solar module according to claim 1, wherein the strings (18) connecting the cells are soldered to the inside of the pane (7, 11) for positional securing of the solar cells (1, 2).

5. The solar module according to claim 1, wherein an antireflective layer (8) is configured on the inside of the front pane (7), in order to prevent an undesirable back reflection from the surface of the solar cells (1, 2) through the front pane (7) to the outside.

6. The solar module according to claim 1, wherein an antireflective coating (10) is applied on the top surface of the front pane (7), the antireflective coating being produced by an embossed texture on the surface of the front pane (7).

7. The solar module according to claim 1, wherein the insulating glass module (4) is sealed on all sides and filled with an inert gas or with air or is evacuated.

8. The solar module according to claim 1, wherein a full-perimeter hollow profile (12) is arranged peripherally which is fixed on one hand to the insides of the front and rear pane using a first adhesive agent (13) and which carries on the face end thereof a sealing means (14) that holds and supports the hollow profile (12) in a sealing manner around the full periphery in the space between the front pane and the rear pane.

9. The solar module according to claim 1, wherein the solder connections (20) serving for the positional securing are additionally provided peripherally as conducting layers (19) and serve for leading the electric contacts (15) in and out, to the outside.

10. The solar module according to claim 1, wherein the string (18) of the solar cells on the underside is eliminated and an electrically conductive connection to the conducting layer (19) configured on the inside of the rear pane is instead produced via a soldered connection (20).

11. The solar module according to claim 1, wherein the string (18) running on the underside of the solar cells (1) are fixed in place in a position-securing manner on the surface of a pane (7, 11) in such a way that conducting layers 19 are applied on one of the panes (7, 11).

12. The solar module according claim 11, wherein the conducting layer consists of a conductive silver paste.

13. The solar module according to claim 1, wherein only in the outer regions are the conducting layers (19) continued so as to form electrically conductive contact areas (22), which are then routed to the outside through or under the hollow profiles 12.

14. A method for producing a solar module comprising an insulating glass composite, wherein the following steps:
1. producing standard commercial solar cells (1, 2) with electrical connection of the associated strings (18), such that this photovoltaic module is electrically conductive and functional;
2. inserting the thus prepared, fully functional photovoltaic module into an opened insulating glass composite, with a front pane (7) still removed;
3. optionally securing the solar cells (1, 2) placed onto one of the panes (7, 11) on the rear pane using a suitable soldering agent (20);
4. affixing the peripheral full-perimeter hollow profile (12) using at least one adhesive agent (13) for fixing the hollow profile (12) to the inside of the rear pane (11);
5. affixing the front pane (7) to the prepared hollow profile (12) with creation of an adhesive contact of the inside of the front pane (7) to the adhesive agent (13) on the hollow profile;
6. applying, using face-end full-perimeter application of a sealing agent (14), for sealing the hollow profile (12) in the insulating glass composite between the front pane (7) and the rear pane (11); and
7. wherein the interior space in the insulating glass module (4) can contain an inert gas or air or can be evacuated.

15. The method according to claim 14, wherein, in substitution of the third process step, the solar cells (1, 2) placed onto one of the panes (7, 11) are secured on the pane using a suitable adhesion-promoting adhesive.

16. The method according to claim 14, wherein the strings (18) that serve for the electrical interconnection of the solar cells (1, 2), are fixed in place by means of a soldered or friction-welded connection (20) on the associated conducting layers (19) capable of being soldered, on the inside of one of the panes (7, 11).

17. The method according to claim 14, wherein the strings configured on the underside are eliminated and the solar cells (1, 2) are soldered directly in an electrically conductive manner to the conducting layers 19 configured on the inside of one of the panes (7, 11).
